(19) United States
(12) Patent Application Publication
(10) Pub. No.: US 2006/0096632 A1
(43) Pub. Date: May 11, 2006

(54) Sealed thin film photovoltaic modules

(76) Inventor: Robert S. Oswald, Williamsburg, VA (US)

Correspondence Address: CAROL WILSON;BP AMERICA INC., MAIL CODE 5 EAST, 4101 WINFIELD ROAD, WARRENVILLE, IL, 60555, US

(21) Appl. No.: 11/314,041

(22) Filed: Dec. 20, 2005

Related U.S. Application Data
(63) Continuation of application No. 10/277,286, filed on Oct. 22, 2002.
(60) Provisional application No. 60/337,897, filed on Nov. 5, 2001.

(51) Int. Cl. H01L 25/00

(52) U.S. Cl. 136/251

(57) ABSTRACT

A sealed photovoltaic module comprising a first substrate, a second substrate, a seal between the first and second substrates positioned at or near the edges of the substrates and forming a sealed chamber defined by the first and second substrates and the seal, and at least one thin film photovoltaic element positioned between the first and second substrate and at least partly within the chamber.

This application claims the benefit of U.S. Provisional Patent Application No. 60/337,897 filed on Nov. 5, 2001.

### FIELD OF THE INVENTION

The present invention relates to sealed photovoltaic modules and methods for their manufacture. More particularly, the present invention relates to sealed photovoltaic modules wherein a thin film photovoltaic element is positioned between at least two substrate plates spaced apart and where the substrate plates are sealed along or near their edges thereby forming a chamber containing at least part of the thin film element. The sealed chamber protects the photovoltaic element from exposure to the environment, particularly from exposure to moisture. The modules of this invention can also be used as building components for walls, roofs, canopies and other structural elements for buildings and other types of construction.

### BACKGROUND OF THE INVENTION

Photovoltaic devices convert light energy, particularly solar energy, into electrical energy. Photovoltaically generated electrical energy can be used for all the same purposes of electricity generated by batteries or electricity obtained from established electrical power grids, but is a renewable form of electrical energy. One type of photovoltaic device is known as a thin film device. These types of devices are suitably manufactured by depositing a photovoltaically active layer or layers onto a suitable plate or sheet of substrate material such as glass, plastic or metal. Two common types of thin film photovoltaic devices comprise amorphous silicon thin films and cadmium sulfide/cadmium telluride (CdS/CdTe) films. The films, once deposited, are generally sandwiched with a second substrate layer made from, for example, transparent glass or transparent plastic, and generally with a clear polymeric-type encapsulating material such as poly ethyl vinyl acetate between the thin film photovoltaic device and the second substrate material, and covering the entire surface of the photovoltaic device. The encapsulant material helps seal the photovoltaic device from exposure to air, moisture and other components of the elements, and also provides structural strength to the completed unit or module containing the photovoltaic elements. Contact of the photovoltaic device with moisture generally causes a reduction in the performance of the device. If sufficient degradation occurs, the device may need to be replaced.

These thin film prior art devices have been used, generally, in the form of an array on the top of roofs or on the sides of buildings and positioned facing the sun to convert sunlight energy into electrical energy.

While such thin film prior art devices are resistant to moisture penetration, the art needs improved photovoltaic devices which have improved resistance to moisture penetration and penetration of other elements from the environment. Also, such prior art photovoltaic devices when used as arrays on roofs do not form part of the structure to which they are attached. Rather, they are added on to the structure. While they provide the benefit of electrical power generation from sunlight, they are not part of the structure of the building.

The art, however, needs to have a photovoltaic device or module which is highly resistant to the effects of the environment, and, in particular, resistant to the penetration of moisture. The art also needs a photovoltaic device that can form part of the structure of a building or other form of construction, be aesthetically appealing from an architectural perspective and preferably serve as a thermal barrier reducing the transfer of heat through the walls or roof of the structure. Such a photovoltaic device or module would generate electric power from sunlight, have an extended useful life, have the dual function of structural element and electric energy generation and provide for the effective, lower cost control of the inside environment of the building. The present invention provides such a photovoltaic device and module and a method for its manufacture.

### SUMMARY OF THE INVENTION

This invention is a sealed photovoltaic module comprising:

a first substrate,

a second substrate,

a seal between the first and second substrates positioned at or near the edges of the substrates and forming a sealed chamber defined by the first and second substrates and the seal,

at least one thin film photovoltaic element positioned between the first and second substrate and at least partly within the chamber.

This invention is also a method for making a photovoltaic module comprising:
(a) forming a thin film photovoltaic device on a first substrate,
(b) sealing the first substrate to a second substrate at or near the edges of the substrates, the substrates being spaced apart, thereby forming a sealed chamber defined by the substrates and the seal wherein the photovoltaic element is at least partially within the chamber.

### BRIEF DESCRIPTION OF THE FIGURES

FIG. 1 is drawing of one embodiment of the sealed photovoltaic module of this invention.

FIG. 2 is a section view of the module shown in FIG. 1.

FIG. 3 is a three-dimensional schematic drawing of a thin film photovoltaic device useful in the sealed module of this invention.

FIG. 4 is a drawing of the steps involved in forming an amorphous silicon thin film photovoltaic device useful in the sealed module of this invention.

FIG. 5 is a three-dimensional schematic drawing of a thin film photovoltaic device useful in the sealed module of this invention.

FIG. 6 is a three-dimensional schematic drawing of an amorphous silicon, partially-transparent thin film photovoltaic device useful in the sealed module of this invention.

FIG. 7 is a three-dimensional schematic drawing of an amorphous silicon, partially-transparent thin film photovoltaic device useful in the sealed module of this invention.

FIG. 8 is a drawing of two embodiments of the sealed module of this invention showing the seal structure in detail.

FIG. 9 is a drawing of an embodiment of the sealed module of this invention.

FIG. 10 is a drawing of an embodiment of the sealed module of this invention.

FIG. 11 is a drawing of an embodiment of the sealed module of this invention.

### DETAILED DESCRIPTION OF THE INVENTION

This invention is a sealed thin film photovoltaic module that has excellent resistance to moisture penetration. In this invention, the photovoltaic device in the module is protected from the external environment by a seal having a low water vapor or moisture transmission rate. This invention also is a sealed thin film photovoltaic module that can be used as a building element such as a facade or outside wall or part thereof, a window, or as a roof on a building or other structure. The sealed photovoltaic module of this invention comprises a first substrate and a second substrate and at least one photovoltaic device positioned between the substrates. Preferably, the photovoltaic device is a thin film device deposited on one of the substrates. The substrates are spaced apart from each other and sealed to one another by a seal that, preferably, runs along the edge of or near the edge of each of the substrates. The substrates are preferably parallel to each other and of the same or about the same size and shape. The space formed due to the separation of the substrates and by the seal which runs along the edge or near the edge of the substrates forms a hollow sealed chamber. The photovoltaic device is at least partially and preferably totally within the hollow chamber. The space in the chamber can comprise air or some other gas, such as, for example, a generally chemically inert gas such as helium, argon or, more preferably, nitrogen. The space can be evacuated or can be at a partial vacuum. However, most preferably, the space in the chamber is filled with air, preferably dry air. The space can also contain a desiccant to help maintain dry air in the chamber.

The sealed chamber shields and protects the thin film photovoltaic components from the atmospheric elements such as exposure to water, oxygen, dust and dirt, wind and other forces which would, in time, cause a deterioration of the condition of the photovoltaic device contained therein. The chamber also forms an insulating space so that when the invented module is used as a building element, for example, as a facade, window, roof or part thereof, the module insulates the inside of the building or other structure from the outside of the structure providing for reduced transmission of heat through the module and permitting improved ambient temperature control within the structure.

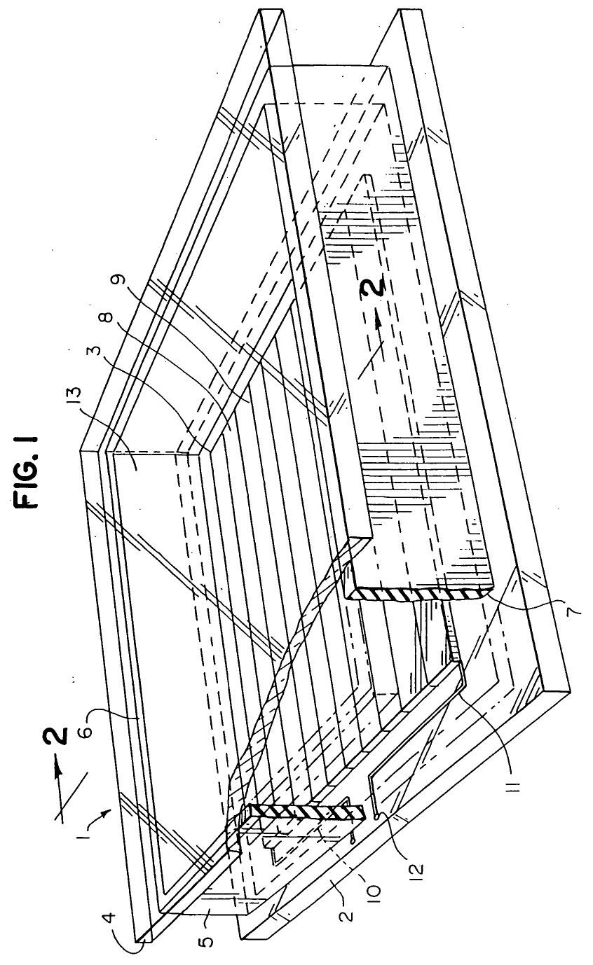

FIG. 1 shows one embodiment of the photovoltaic module 1 of this invention. In FIG. 1, a transparent glass substrate 2 has deposited thereon a thin film photovoltaic device 3. A second glass substrate 4 is sealed to glass substrate 2 by seal 5. Seal 5, preferably, comprises plastic, rubber or other suitable material that will form a durable and structurally sound seal. Seal 5, as shown in FIG. 1, is positioned near the edge of the glass substrates. Sealing surfaces 6 and 7 show that the seal 5 is in contact with the glass substrates 2 and 4 along the entire perimeter of the seal thereby forming a hermetically sealed chamber 13 bounded by the inside surfaces of the first and second glass substrates and the inner surface of seal 5. Thin film photovoltaic device 3 comprises a plurality of individual photovoltaic cells 8 each connected in series by interconnects 9. Electrical conduits 10 and 11 lead to connector 12 for connecting the module to a device or other system that will use the electric current generated by the photovoltaic module when the photovoltaic module is exposed to light. Connector 12 is shown as extending through seal 5 with seal 5 forming a close, airtight seal around connector 12.

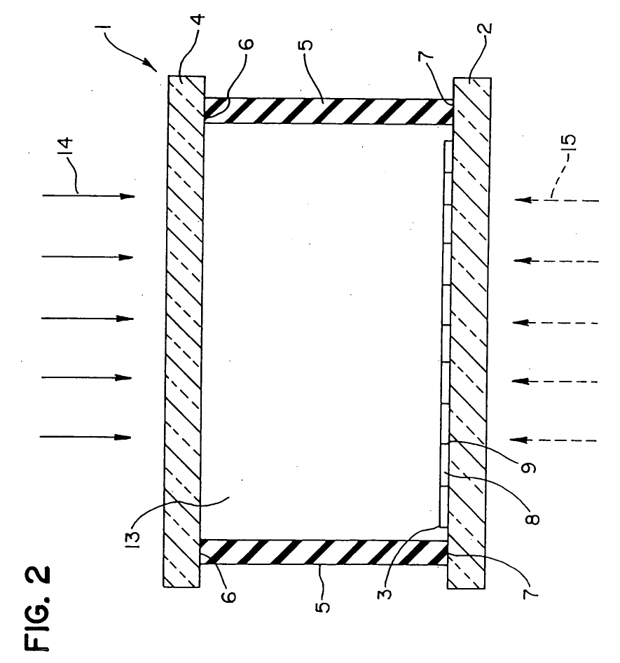

FIG. 2 is a sectional view of the photovoltaic module shown in FIG. 1 viewed from the direction shown in FIG. 1. For convenience, the numerals in FIG. 2 correspond to the same elements shown in FIG. 1.

In FIG. 2, light rays 14 are shown as impinging on the photovoltaic device first onto substrate 4 side of the module rather than substrate 2 side of the module. In that embodiment of the invention, thin film photovoltaic element 3 has its light receiving side facing the chamber. Thus, light rays 14 entering the module from and on substrate 4 side of the module pass through the glass substrate material 4 and impinge on the photovoltaically active surface of thin film photovoltaic element 3. In another embodiment, the photovoltaically active layer or layers of the thin film photovoltaic device 3 can face the substrate 2 side of the module. In that embodiment, light rays depicted by dashed lines 15 impinging on substrate 2 side of the module would be converted to electrical energy by the photovoltaic element 3.

The substrates used to form the photovoltaic modules of this invention can be glass, such as soda-lime glass or a low iron glass, a durable, strong polymeric material such as a polyimide, or a metal film such as aluminum, steel, titanium, chromium, iron, and the like. If one of the substrates used to make the module is opaque, such as a metal substrate, the other substrate is made of a light transmissive material such as glass or clear plastic. The light transmissive substrate provides for light entering the module to interact with the photovoltaic device within the chamber of the sealed module. Glass, particularly a highly transparent or transmissive glass, is preferred. The substrate is preferably flat but can, depending on the particular use of the module, have curvature or other shape that is not flat. The substrate can be any size. Generally, however, for most architectural applications, the substrate will be made of flat glass and will range in size from about 4 or 10 square feet to about 200 square feet and will be preferably be either rectangular or square in shape, although the exact shape is not limited. The thickness of the substrate is also variable and will, in general, be selected in view of the application of the module. If, for example, the module uses glass as the substrate, the thickness of the glass can range in thickness from about 0.088 inch to about 0.500 inch, more preferably from about 0.125 inch to about 0.250 inch. If the glass will be used in large dimensions, such as, for example, at least about 60, or at least about 200 square feet, the glass will preferably have a thickness of at least about 0.125 inch, more preferably of at least about 0.187 inch. When the glass substrate has a thickness of at least about 0.187 inch or at least about 0.250 inch, it will preferably be a low iron glass. Low iron means, preferably, that the glass has no more than about 0.1 wt % iron, more preferably less than about 0.1 wt % iron.

The photovoltaic device in the module of this invention is positioned at least partially and preferably completely within the sealed chamber of the module. The thin film photovoltaic device is preferably positioned on one of the substrates. Most preferably, the thin film photovoltaic device is manufactured by depositing onto one of substrates the thin film layer or layers comprising the thin film photovoltaic device. The type of thin-film device used in the sealed photovoltaic module of this invention can be any thin film device. For example, it can be an amorphous silicon device or a CdS/CdTe device. By amorphous silicon device we mean at least one layer of the device is or comprises amorphous silicon. The thin film photovoltaic devices preferably contain at least one PIN type, at least one NIP type of layer structure or at least one PN structure. Most preferably, the thin film photovoltaic device is either an amorphous silicon device or a CdS/CdTe device. Such photovoltaic devices are known in the art and can be deposited onto a suitable substrate material such as glass or metal by known methods. For example, methods for forming amorphous silicon devices which can be used in this invention are set forth in U.S. Pat. Nos. 4,064,521, 4,292,092, UK Patent Application 9916531.8 (Publication No. 2339963, Feb. 9, 2000) all of which are incorporated herein by reference.

Methods for making photovoltaic (PV) elements useful in the module of this invention are known to those of skill in the art. For example, methods for making CdS/CdTe PV elements and PV devices are described in N. R. Pavaskar, et al., J. Electrochemical Soc. 124 (1967) p. 743; I. Kaur, et al., J. Electrochem Soc. 127 (1981) p. 943; Panicker, et al., “Cathodic Deposition of CdTe from Aqueous Electrolytes,” J. Electrochem Soc. 125, No. 4, 1978, pp. 556-572; U.S. Pat. No. 4,400,244; EP Patent 244963; U.S. Pat. No. 4,548,681; EP Patent 0538041; U.S. Pat. No. 4,388,483; U.S. Pat. No. 4,735,662; U.S. Pat. No. 4,456,630; U.S. Pat. No. 5,472,910; U.S. Pat. No. 4,243,432; U.S. Pat. No. 4,383,022; “Large Area Apollo® Module Performance and Reliability” 28^{th} IEEE Photovoltaic Specialists Conference, Anchorage, Alaska, September 2000; all of which are incorporated by reference herein. Also incorporated by reference is U.S. Provisional Patent Application 60/289481 filed on May 8, 2001.

Thin film amorphous silicon photovoltaic devices containing at least one PIN or NIP structure, and suitable for use in the sealed module of this invention, will now be described.

Photovoltaic cells that convert radiation and particularly solar radiation into usable electrical energy can be fabricated by sandwiching certain semiconductor structures, such as, for example, the amorphous silicon PIN structure disclosed in U.S. Pat. No. 4,064,521, between two electrodes. One of the electrodes typically is transparent to permit solar radiation to reach the semiconductor material. This “front” electrode (or contact) can be comprised of a thin film (e.g., less than 10 micrometers in thickness) of transparent conductive oxide material, such as zinc oxide or tin oxide, and usually is formed on the transparent supporting substrate made of glass or plastic, as described above. The “back” or “rear” electrode (or contact), which is formed on the surface of the semiconductor material opposite the front electrode, generally comprises a thin film of metal such as, for example, -aluminum or silver, or the like, or a thin film of metal and a thin film of a metal oxide such as zinc oxide between the semiconductor material and the metal thin film. The metal oxide can be doped with boron or aluminum and is typically deposited by low-pressure chemical vapor deposition.

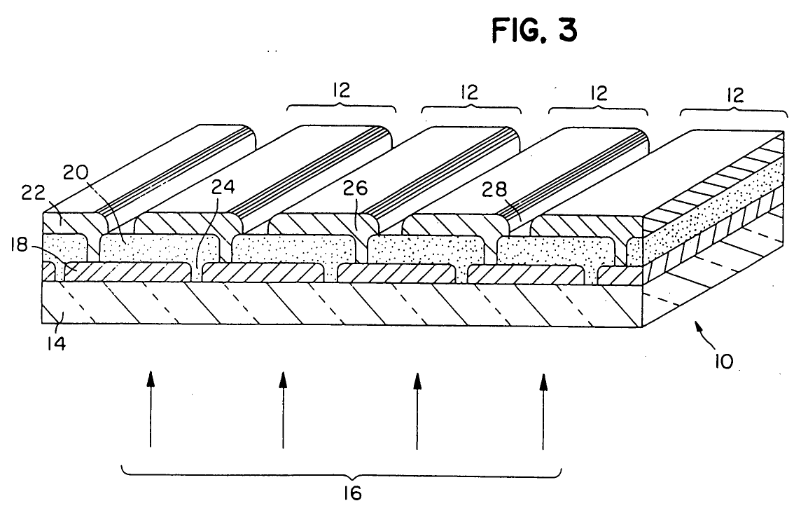

FIG. 3 shows thin-film amorphous silicon photovoltaic module 10 comprised of a plurality of series-connected photovoltaic cells 12 formed on glass substrate 14, and subjected to solar radiation or other light 16 passing through substrate 14. (A photovoltaic device having a series of photovoltaic cells is also called a module.) Each photovoltaic cell 12 includes a front electrode 18 of transparent conductive oxide, a transparent photovoltaic element 20 made of a semiconductor material, such as, for example, hydrogenated amorphous silicon, and a back or rear electrode 22 of a metal such as aluminum. Photovoltaic element 20 can comprise, for example, a PIN structure. Adjacent front electrodes 18 are separated by first grooves 24, which are filled with the semiconductor material of photovoltaic elements 20. The dielectric semiconductor material in first grooves 24 electrically insulates adjacent front electrodes 18. Adjacent photovoltaic elements 20 are separated by second grooves 26, which are filled with the metal of back electrodes 22 to provide a series connection between the front electrode of one cell and the back electrode of an adjacent cell. These connections are referred to herein as “interconnects.” Adjacent back electrodes 22 are electrically isolated from one another by third grooves 28.

The thin-film amorphous silicon photovoltaic module of FIG. 3 typically is manufactured by a deposition and patterning method. One example of a suitable technique for depositing a semiconductor material on a substrate is glow discharge in silane, as described, for example, in U.S. Pat. No. 4,064,521. Several patterning techniques are conventionally known for forming the grooves separating adjacent photovoltaic cells, including silkscreening with resist masks, etching with positive or negative photoresists, mechanical scribing, electrical discharge scribing, and laser scribing. Silkscreening and particularly laser scribing methods have emerged as practical, cost-effective, high-volume processes for manufacturing thin-film semiconductor devices, including thin-film amorphous silicon photovoltaic modules. Laser scribing has an additional advantage over silkscreening because it can separate adjacent cells in a multi-cell device by forming separation grooves having a width less than 25 micrometers, compared to the typical silkscreened groove width of approximately 300-500 micrometers. A photovoltaic module fabricated with laser scribing thus has a large percentage of its surface area actively engaged in producing electricity and, consequently, has a higher efficiency than a module fabricated by silkscreening. A method of laser scribing the layers of a photovoltaic module is disclosed in U.S. Pat. No. 4,292,092.

Referring to FIG. 3, a method of fabricating a multi-cell photovoltaic module using laser scribing comprises: depositing a continuous film of transparent conductive oxide on a transparent substrate 14, scribing first grooves 24 to separate the transparent conductive oxide film into front electrodes 18, fabricating a continuous film of semiconductor material on top of front electrodes 18 and in first grooves 24, scribing second grooves 26 parallel and adjacent to first grooves 24 to separate the semiconductor material into individual photovoltaic elements 20 (or “segments”) and expose portions of front electrodes 18 at the bottoms of the second grooves, forming a continuous film of metal on segments 20 and in second grooves 26 so that the metal forms electrical connections with front electrodes 18, i.e., the interconnects, and then scribing third grooves 28 parallel and adjacent to second grooves 26 to separate and electrically isolate adjacent back electrodes 22. As shown in FIG. 3, the third grooves 28 are scribed in the metallic back electrode from the back contact side or face of the photovoltaic cell. The first and last cell of a module generally have bus bars which provide for a means to connect the module to wires or other electrically conductive elements. The bus bars generally run along the length of the outer, long portion of the first and last cell.

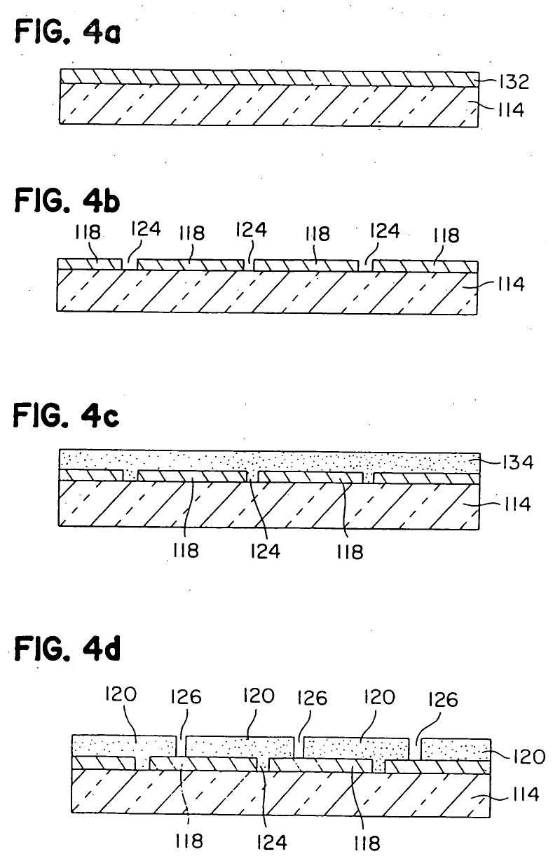

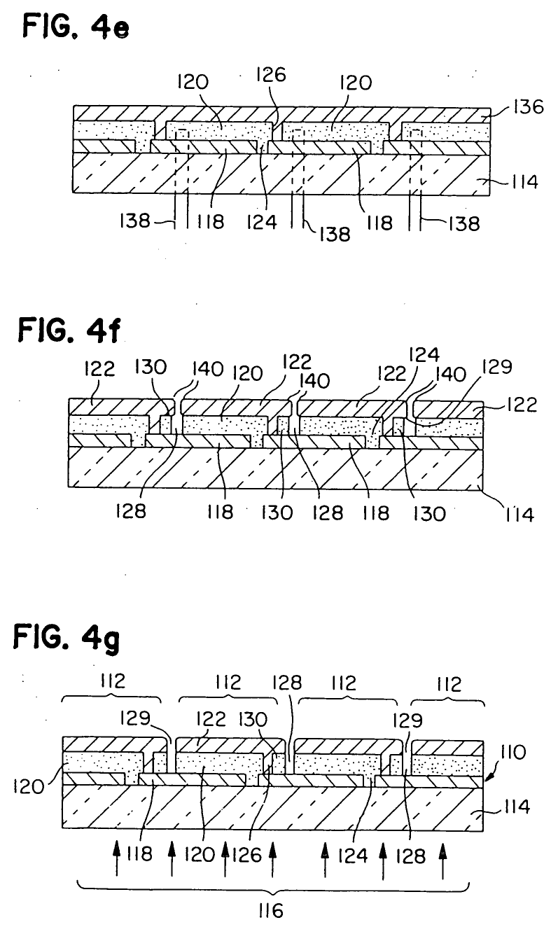

FIG. 4(g) is a schematic cross sectional view of a portion of a multi-cell thin-film photovoltaic module, designated generally by reference numeral 110, deposited on a substrate 114. Photovoltaic module 110 is comprised of a plurality of series-connected photovoltaic cells 112 formed on a flat, transparent substrate 114. In operation, photovoltaic module 110 generates electricity in response to light, particularly solar radiation, 116 passing through substrate 114, which preferably is formed of glass. Each photovoltaic cell 112 includes a front electrode segment 118 of transparent conductive oxide, a photovoltaic element 120 made of semiconductor material, such as, for example, hydrogenated amorphous silicon, and a back electrode 122 comprising a metal, preferably aluminum and optionally a metal oxide such as zinc oxide. Adjacent front electrode segments 118 are separated by first grooves 124, which are filled with the semiconductor material of photovoltaic elements 120. Adjacent photovoltaic elements 120 are separated by second grooves 126 and also by third grooves 128. An inactive portion 130 of semiconductor material is positioned between second groove 126 and third groove 128. Portions 130 are “inactive” in the sense that they do not contribute to the conversion of light 116 into electricity. Second grooves 126 are filled with the material of back electrodes 122 to provide a series connection between the front electrode of one cell and the back electrode of an adjacent cell. These connections are referred to as interconnects. Gaps 129, located at the tops of third grooves 128, separate and electrically isolate adjacent back electrodes 122. A series of photovoltaic cells 112, as shown in FIG. 4(g), comprise a module. The module can have a large number of individual cells. Two or more modules can be connected in parallel to increase the current of the photovoltaic device. If a series of photovoltaic cells 112 is used, the contact of the first and last cell must be available for attaching a wire or other conductive element in order to connect the module to a device that will use the electric current generated by the module. Generally, as mentioned above, a conductive strip or “bus bar” is added to the outside of the first and last cell in the module (i.e., parallel to the grooves). These bus bars are used to make the electrical connection to the device that will utilize the electrical current generated when the module is exposed to light. Typically, they extend to a region near the central part of one edge of the substrate to provide a convenient contact for contacting the module to the device or system that will use the electricity generated by the module.

A method for making a suitable amorphous silicon photovoltaic device will now be described with reference to FIGS. 4(a) through 4(g). Conductive tin oxide (CTO), preferably a fluorinated tin oxide, is deposited on a substrate, preferably glass, to form a front contact layer 132, or glass having the conductive tin oxide already deposited thereon can be obtained from suitable glass suppliers. The tin oxide layer can have a smooth or textured surface. The textured surface is preferred for application of the photoelectric device of this invention where the greatest electric generating efficiency is desired. However, where the least amount of distortion of light coming through the photovoltaic module is desired, a smooth tin oxide surface -is preferred. Such lower distortion, photovoltaic cells and modules are particularly useful as windows or in other applications where minimizing distortion of the transmitted light is desired. Next, a strip conductive material, preferably a silver (Ag) containing material, is deposited on the outside edges of two opposite sides of CTO layer 132 to form bus bars. The bus bars preferably lead up to a region located near the center of one side of the substrate and end in solder points for positive and negative electrical contacts to the photovoltaic device. Although the application of such bus bars made from fritted materials is disclosed in U.S. Pat. No. 5,593,901, which is incorporated herein by reference, generally, a desired pattern for the bus bars can be applied by depositing a suitable conductive fluid on the substrate where the conductive fluid comprises a conductive metallic or organometallic component such as silver, copper, nickel, aluminum, gold, platinum, palladium, or mixtures thereof. The conductive fluid may also preferably comprise a carrier fluid which aids in the transmission of the conductive metallic or organometallic components. The conductive fluid should provide a conductive fluid which is relatively homogeneous and of proper viscosity for deposition in the desired pattern. The viscosity should not be so low as to provide a runny fluid which is difficult to control or which might separate out various components, nor should the viscosity be so high as to plug deposition equipment or be difficult to pattern evenly. Preferably, the carrier fluid can be removed from the conductive fluid at conditions which are not extreme and would not lead to deterioration of the conductive material or-the substrate. It is preferable that the carrier fluid be removable by subjecting the conductive fluid to moderate heat for a short period of time. The conductive fluid may desirably also comprise glass frits which can help form a conductive material having improved mechanical strength and adhesion properties to the substrate. When glass frits are used, it is desirable to heat the conductive fluid for a period after deposition on the substrate to sinter the glass frit and form conductive material having the desired properties. The temperature and time necessary for this step may vary depending on the nature of the conductive fluid including the frit but generally the temperature ranges from about 500° C. to about 700° C.

Metech 3221, manufactured by Metech, Inc. of Elverson, Pa., USA, has been found to be a suitable conductive fluid for this type of process and is a paste comprised of silver particles and glass frit in binder and solvent. This material may be 65% by weight silver having a resistivity of <2.0 milliohms/sq. and a viscosity of 4-8 kcps. The conductive fluid can be dispensed by any suitable means such as, for example, the system available from Electronic Fusion Devices having a 725 D valve and positioned in the desired pattern by an Asymtek 402 B positioning system.

Following thermal cure, if required, of the conductive material, the front contact layer 132 is laser scribed to form scribe lines 124. Following laser scribing of scribe lines 124, the remaining steps in the fabrication of the photovoltaic device as shown in FIGS. 4(c) to 4(g) as described herein are performed as described below.

It should be noted that in FIGS. 4(a) to 4(g), the front contact layer 132 is shown but the bus means are not. It should be understood, however, that bus means are disposed on front contact layer 132 in the manner described above following which the steps shown in FIGS. 4(c) to 4(g) are performed.

A photovoltaic region comprised of a substantially continuous thin film 134 of semiconductor material is fabricated over front electrodes 118 and in first grooves 124, as shown in FIG. 4(c). The semiconductor material filling first grooves 124 provides electrical insulation between adjacent front electrodes 118. Preferably, the photovoltaic region is made of hydrogenated amorphous silicon in a conventional PIN structure (not shown) and is typically up to about 5000 Å in thickness, being typically comprised of a p-layer suitably having a thickness of about 30 Å to about 250 Å, preferably less than 150 Å, and typically of about 100 Å, an i-layer of 2000-4000 Å, and an n-layer of about 200-400 Å. Deposition preferably is by glow discharge in silane or a mixture of silane hydrogen, as described, for example, in U.S. Pat. No. 4,064,521. Alternatively, the semiconductor material may be CdS/CuInSe₂ or CdS/CdTe. The semiconductor layer can comprise a single PIN type layer. However, the photovoltaic devices of this invention can have other semiconductor layers; for example, can be a tandem or triple-junction structure.

The semiconductor film 134 is then scribed with a laser to ablate the semiconductor material along a second predetermined pattern of lines and form second grooves 126, which divide semiconductor film 134 into a plurality of photovoltaic elements 120, as shown in FIG. 4(d). Front electrodes 118 are exposed at the bottoms of second grooves 126. Scribing may be performed with the same laser used to scribe transparent conductive oxide layer 1.32, except that power density is typically reduced to a level that will ablate the semiconductor material without affecting the conductive oxide of front electrodes 118. The laser scribing of semiconductor film 134 can be performed from either side of substrate 114. Second grooves 126 preferably are scribed adjacent and parallel to first grooves 124 and preferably are approximately about 20 to about 1000 micrometers in width.

A thin film of metal 136, preferably aluminum, is fabricated over photovoltaic elements 120 and in second grooves 126, as shown in FIG. 4(e). The conductive material filling second grooves 126 provides electrical connections between film 136 and the portions of front electrodes 118 exposed at the bottoms of second grooves 126. Conductive film 136 is formed, for example, by sputtering or by other known techniques. The thickness of film 136 depends on the intended application of the module. As an example, for modules intended to generate sufficient power to charge a 12-volt storage battery, metal film 136 typically is formed of aluminum and is about 2000-6000 Å thick.

The next step is to scribe metal film 136 with a laser to ablate the metal along a pattern of lines and form a series of grooves dividing film 136 into a plurality of back electrodes. One such method, is taught, for example, in U.S. Pat. No. 4,292,092. Because of the high reflectivity of aluminum and other metals conventionally used to form the back electrodes, the laser used to scribe the back electrode is usually operated at a significantly higher power density than those used to scribe second grooves 126 in semiconductor film 134, often 10 to 20 times higher.

For example, if metal film 136 is formed of aluminum and is about 7000 Å thick, and if the aluminum is to be directly ablated by a frequency-doubled neodymium:YAG laser emitting light having a wavelength of about 0.53 micrometers and operated in a TEM.sub.00 (spherical) mode, the laser typically would be focused to about 0.25 micrometers and operated at about 300 mW. Shorter pulse duration may reduce average laser power requirements. When the same laser is used to ablate semiconductor film 134 and form second grooves 126, it is preferably defocused to 100 micrometers and operated at about 360 mW. Although the laser would be operated at a slightly lower power level for direct ablation of aluminum, the number of photons per second per unit area, that is, the power density of the laser, is also a function of the spot size of the laser beam. For a given power level, power density varies inversely with the square of the radius of the spot. Thus, in the example described above, the laser power density required for direct ablation of the aluminum film is about 13 times the power density required to ablate the amorphous silicon film.

It is difficult to prevent a laser operating at the power density necessary for direct ablation of aluminum from damaging the underlying semiconductor material. Specifically, the photovoltaic cell may become shorted due to molten metal flowing into the scribed groove and electrically connecting adjacent back electrodes, or due to molten metal diffusing into the underlying semiconductor material and producing a short across a photovoltaic element. In addition, where the underlying semiconductor material is comprised of amorphous silicon, the underlying amorphous silicon material may recrystallize. Moreover, in an amorphous silicon PIN structure, dopants from the n-layer or p-layer may diffuse into the recrystallized amorphous silicon of the i-layer.

Therefore, after fabrication of metal film 136, the photovoltaic regions 120 underlying metal film 136 are preferably scribed with a laser operated at a power density sufficient to ablate the semiconductor material along a predetermined pattern of third lines parallel to and adjacent second grooves 126 but insufficient to ablate the conductive oxide of front electrodes 118 or the metal of film 136. More specifically, the laser must be operated at a power level that will ablate the semiconductor material and produce particulates that structurally weaken and burst through the portions of the metal film positioned along the third lines to form substantially continuous gaps in the metal film along the third lines and separate the metal film into a plurality of back electrodes. As shown in FIG. 4(e), where the laser beams are shown schematically and designated by reference numerals 138, laser patterning of metal film 136 by ablation of the underlying semiconductor material is performed through substrate 114.

Ablating the semiconductor material of photovoltaic regions 120 along the pattern of third lines forms third grooves or scribes 128 in the semiconductor material, as seen in FIG. 4(f). Third grooves 128 preferably are about 100 micrometers wide and are spaced apart from second grooves 126 by inactive portions 130 of semiconductor material. As described above, the ablation of the semiconductor material formerly in third grooves 128 produces particulates, (for example, particulate silicon from the ablation of amorphous silicon,) which structurally weaken and burst through the portions of metal film 136 overlying the ablated semiconductor material to form gaps 129 that separate film 136 into a plurality of back electrodes 122.

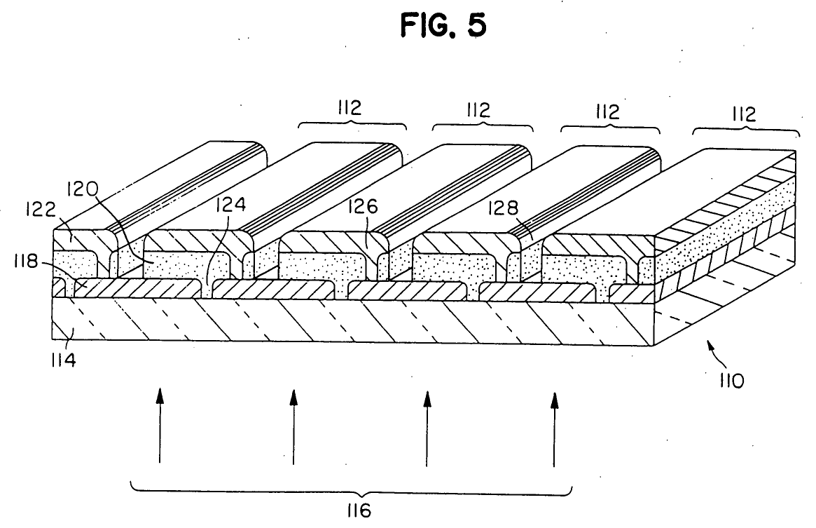

Gaps 128 are preferably substantially continuous as viewed along a line orthogonal to the plane of FIG. 4(f). The laser parameters required to produce continuous gaps 129 in metal film 136 will, of course, depend on a number of factors, such as the thickness and material of the metal film, the characteristic wavelength of the laser, the power density of the laser, the pulse rate and pulse duration of the laser, and the scribing feed rate. To pattern a film of aluminum having a thickness of about 2000-6000 Å by ablation of an underlying amorphous silicon film approximately 6000 Å in thickness with a frequency-doubled neodymium:YAG laser emitting light having a wavelength of about 0.53 micrometers, when the pulse rate of the laser is about 5 kHz, and the feed rate is about 13 cm/sec, the laser can be focused to about 100 micrometers in a TEM.sub.00 (spherical) mode and operated at about 320-370 mW. Under the above conditions, when the laser is operated at less than about 320 mW, portions of metal film 136 may remain as bridges across third grooves 128 and produce shorts between adjacent cells. When the laser is operated above about 370 mW, continuous gaps 129 may be produced, but the performance of the resulting module, as measured by the fill factor, may be degraded. Although the precise cause of degraded performance presently is unknown, we believe that the higher laser power levels may cause melting of portions of the amorphous silicon photovoltaic elements that remain after third grooves 128 are ablated. In addition, the increased power densities may cause the laser to cut into front electrodes 118, which would increase series resistance and, if the power density is sufficiently high, might render the module inoperable by cutting off the series connections between adjacent cells. FIG. 5 is a schematic, three-dimensional drawing of the module of FIG. 4(g).

The photovoltaic device just described would, because it has a back electrode or back or rear contact comprising a thin film of aluminum, be essentially opaque. If such a device is used in the sealed module of this invention, and if the photovoltaic device covered all or substantially all of the surface area of one of the substrates of the sealed module, the module would be essentially opaque. Such a module could be used in buildings or other construction where it is not necessary or desirable to see through the module; for example, in roofs, facades or in parts or the building where it is not desirable to have transparency. However, if it is desirable to see through the sealed module such as, for example, a window or skylight, each of the substrates comprising the module and the photovoltaic device needs to be transparent or at least semitransparent or partially transparent. A semitransparent or partially transparent photovoltaic device can be manufactured by using contacts that are made of a conductive transparent material such as described above for the front contact or electrode. However, the light exiting a thin film amorphous silicon photovoltaic device made as such generally has a red color which is not generally desirable for the interior of buildings.

Another method to make a semitransparent thin film amorphous silicon photovoltaic device is to remove a portion of the metal back contact. The amount removed should be an amount that provides for a desirable amount of transparency without compromising the efficiency of the device in converting light energy into electrical energy. Suitable semitransparent or partially transparent thin film amorphous silicon photovoltaic devices are described in U.S. Provisional Application 09/891,752 filed on Jun. 26, 2001, incorporated herein by reference. These amorphous silicon thin film photovoltaic cells and modules can be made partially transparent by scribing the back metal contact. The back contact can be removed in a specified pattern on the photovoltaic cell or module using a laser, preferably a computer-controlled laser, such that the cell or module can have a logo or other sign so that when the photovoltaic cell or module is viewed the logo or sign is highly noticeable. The photovoltaic module therefore functions both as a means for generating electric current and as a source of information such as an advertisement or means of identification. If it is desirable to have a photovoltaic module that transmits light without regard to the need to have a logo or other design or information on the photovoltaic cell, a highly efficient means for making such a module comprises scribing with a laser, or otherwise forming lines or interconnecting holes through the back contact and in a direction that crosses the direction of the interconnects of the photovoltaic module. Preferably, such scribe lines are perpendicular, or nearly so, to the direction of the interconnects. It is also preferable that such scribe lines run completely across the photovoltaic module up to but not crossing the bus bars of the first and last cells of the series of cells in a module. The number of such scribes which are made on the back contact will determine the degree of transparency. Of course, for each scribe, that amount of area of the cell becomes photovoltaically inactive. However, the scribes made in the manner described above, particularly where the scribe comprises a series of connected holes to form a line, provide for the least amount of loss of photovoltaic activity.

In the preferred thin film photovoltaic devices used in the sealed module of this invention, a portion of the back metal contact of the amorphous silicon thin film photovoltaic devices is selectively removed or ablated by lasers to form a design on the back contact, or is scribed to produce a partially transparent photovoltaic module. The scribing can be done by any means such as masking and etching or by mechanical scribing. However, the preferred method for removing part of the rear contact is to use a laser. As described above, the selective removal of the metal of the rear contact can be accomplished in such a manner as to impart a design, lettering or logo to the photovoltaic module. This can be done to achieve shading, textures or three-dimensional effects. The particular design or lettering or other feature to be added to the photovoltaic module can be stored in a computer or other memory system, and such stored information can be recalled during the manufacturing process to quickly and accurately reproduce the desired design, lettering, logo or other feature on the photovoltaic module by directing the laser to scribe the pattern on the module by selectively removing the appropriate portions of the back contact.

If only transparency and not a design is desired, the rear contact can be scribed, again by one or more of the techniques mentioned above, to remove at least some of the back contact. Preferably, a laser scribing process is used for this procedure as well. Preferably, such scribing is accomplished by scribing lines or grooves across the module in a pattern that crosses the interconnects, i.e., the scribe lines to produce partial transparency cross rather than run parallel to the interconnects. Preferably, the scribe lines or grooves that are used to produce partial transparency of the photovoltaic module run perpendicular to the direction of the interconnects. Preferably, the scribe lines for producing partial transparency are parallel to each other. The number of scribes that are added to the photovoltaic module to produce partial transparency of the module can vary depending on the desired transparency. Also, the width of each scribe can vary depending on the desired transparency. Generally, the amount of back contact removed by the scribing is no more than about 50 percent of the area of the back contact, more preferably no more than about 20 percent of the back contact and most preferably no more than about 10 percent of the back contact. As stated above, the greater amount of the back contact removed, the more transparent the photovoltaic module will be. However, the more contact removed, the less effective the module will be in generating electrical current when exposed to sunlight or other light sources. Generally, the spacing of the scribe lines is about 0.5 to about 5 millimeters (mm), more preferably about 0.5 to about 2 mm and most preferably about 0.5 to about 1.0 mm. The width of each scribe line is preferably about 0.5 to about 0.01 mm, more preferably about 0.2 to about 0.05 mm. The scribe line can be a solid line if, for example, a laser scribing technique is used to form the line where the laser beam is projected as a linear beam. The scribe lines can also be in the form of a series or row of holes. The holes can be of any shape such as circles, squares or rectangles. Preferably, the scribe lines are a series of small holes. The holes can be connected or not connected, or only some connected. The holes are preferably connected or overlap so as to form a continuous scribe across all or a part of the surface of the photovoltaic module but not including the bus bars. Most preferably, the scribing is in the form of circular holes having a diameter of at least about 0.01 mm, preferably about 0.1 to about 0.2 mm. We have determined that circular holes, particularly when they are interconnected, lead to minimized power loss and maximized light transmission.

When a laser is used to remove parts of the back contact to form the photovoltaic modules of this invention having the design or other such feature imparted to the photovoltaic module, or to form the photovoltaic module of this invention which is partially transparent, the laser used to remove the desired sections of the back contact is preferably a continuous wave laser or more preferably a pulsed laser. The laser can be an ultraviolet laser such as an Excimer laser, for example a KrF or ArCl laser and the like, or a third or forth harmonic of Nd:YAG, Nd:YLF and Nd:YVO₄ lasers. The laser can also be a visible or infrared laser. Most preferably, the laser used is a visible laser, preferably a green laser; for example, a frequency doubled Nd—YAG, Nd—YLF or Nd—YVO₄ laser. The laser can be directed to the top of the back contact so that the back contact is directly ablated or removed by the laser. In a preferred technique, the laser beam is directed through the transparent substrate and through the transparent PIN component layers to ablate the rear contact. In a preferred method of operation, the laser is used to generate shock waves by using short pulses of high laser beam energy. This enhances the removal of the back contact and reduces shunting. After the removal of the back contact, particularly after using the laser method, the photovoltaic cell is preferably cleaned, preferably using an ultrasonic bath. The cleaning process removes dust particles and melted materials along the edges of the scribe patterns, thereby reducing shunting. The cleaning, particularly high power ultrasonic cleaning, results in the recovery of as much as 3 percent of the cell's power that would otherwise be lost if such cleaning was not conducted.

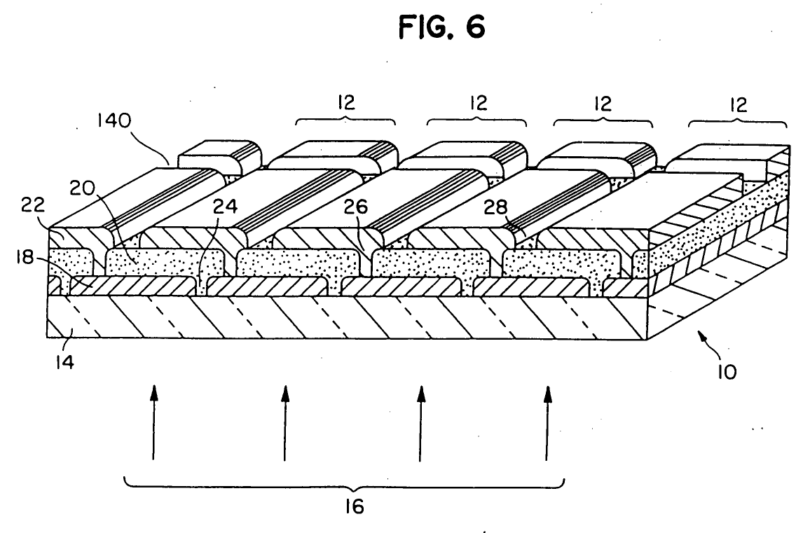

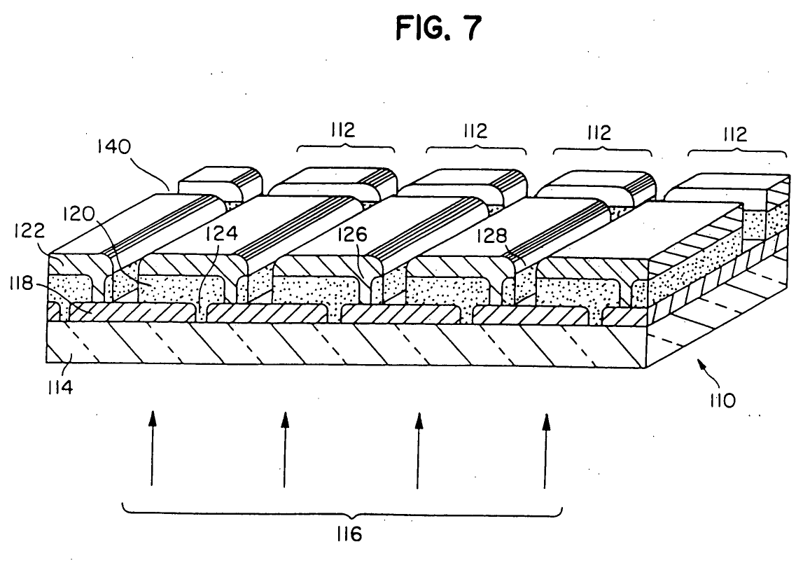

FIGS. 6 and 7 show a three-dimensional representation of one transparency groove 140 in the photovoltaic module. FIGS. 6 and 7 are the same as FIGS. 3 and 5, respectively, except that transparency groove or scribe 140 has been added. Elements numbered in FIGS. 3 and 5 are the same elements as numbered in FIGS. 6 and 7, respectively. In the actual module, the number of such grooves 140 would be increased and spaced, shaped and sized as described hereinabove, in order to provide for the desired level of transparency. As shown in FIG. 6, the groove or scribe 140 extends only through the metal layer 22 to semiconductor layer 20. As shown in FIG. 7, the groove. 140 extends from the metal back contact layer 122 down to the first contact 118. In FIG. 7, the groove is represented as a straight-sided groove. However, as described above, this groove can be a series of connected holes.

Although removal of the metal back contact layer by laser scribing to form the partially transparent photovoltaic modules and cells or to form the photovoltaic modules having designs, logos, lettering or other features can be accomplished using the techniques described hereinabove for producing gaps or grooves 128 and 129 in FIGS. 4, 5 and 7, a preferred method is to use a high repeating rate, high power laser such as Nd:YVO₄ laser, preferably, at about 20-100 kHz at a rapid scribing speed of, for example, about 10-20 meters per second with a spot size of, for example, 0.1 to about 0.2 mm. Such conditions can be used to form a partially transparent photovoltaic module 48 inches by 26 inches having, for example, a 5% transmission in less than about one minute. The laser beam passes through a telescope and is directed to XY scanning mirrors controlled by galvanometers. The XY scanning mirrors deflect the laser beam in the X and Y axes. The telescope focuses the beam onto the photovoltaic module and scribing rates of about 5 to 20 meters per second are achieved by this method. In another method, using a high power Eximer laser and cylindrical optics, an entire scribe line can be made in a single laser pulse. Such a laser scanning or single laser pulse technique can be used to form the interconnect and other scribe lines to form the series arranged photovoltaic cells or modules described herein, i.e., scribes or grooves 124, 126 and 128 as shown in FIGS. 5, 6 and 7.

In another embodiment of this invention, rather than space the grooves or scribe lines evenly across the surface of the photovoltaic cells and module to form the partially transparent photovoltaic cells and modules, the scribes or grooves to produce the partial transparency can be grouped in bands where, in each band, each scribe line is closely spaced. Bands of closely spaced scribe lines alternate with bands having no or very few scribes or grooves for partial transparency. A photovoltaic module made in such a manner with alternating bands has a Venetian Blind-like appearance. Such a photovoltaic module is aesthetically appealing. In one such embodiment, high transmission bands, for example, bands about 0.5 to 2 cm wide with transmission of 20-40%, are alternated with opaque bands, for example, having a transmission of less than about 5%, more preferably less than about 1%, and having a width of about 0.5 to about 1.0 cm.

Following the laser scribing to form the partially transparent thin film photovoltaic device, it is preferable to anneal the device. Annealing the device improves performance of the module, for example, by decreasing shunting loss. For example, the scribed device can be annealed in air at a temperature of 150 to about 175° C. for 0.5 to about 1.0 hour.

Partial or semi-transparency can also be achieved by using a substrate where the thin film photovoltaic devices do not cover the entire surface of the substrate, leaving areas or regions on the substrate that are transparent. The regions with no photovoltaic device deposited thereon can be in the form of a border at the edges of the substrate and thus the edges of the module, a center portion, stripes or bands. Other shapes are possible, and they can range in size and quantity. For example, about 5% to about 95% of the surface area of the substrate may have the photovoltaic device deposited thereon with the remaining area remaining transparent.

In the sealed thin-film photovoltaic module of this invention, at least part and preferably the entire thin film photovoltaic device is contained within the chamber of the sealed-module. In the preferred embodiment, the thin film photovoltaic device deposited on glass or other substrate is sealed to another substrate, preferably glass, to form the sealed module having a chamber bounded by the inner surfaces of the substrates and the inner side of the seal. This sealing can be accomplished by spacing the substrates and providing for a sealing system preferably around the perimeter, or close to the perimeter, of the thin film photovoltaic device, sealing the two substrates together with the side of the substrate containing the thin film photovoltaic device deposited thereon facing the chamber formed by the sealed substrates. As discussed above, the substrates can be any shape but are preferably square or rectangular and are preferably flat.

The substrates are preferably spaced from each other about 0.1 to about 2.0 inches, more preferably about 0.1 to about 1.5 inch, or about 0.1 to about 1.0 inch. However, the exact spacing will depend on the use of the sealed module. Preferably, the substrates are spaced at least about 0.15 inch or 0.2 inch apart or, if used as a part of a window, for example, with a semi- or partially transparent photovoltaic device, at least about 0.625 inches apart. Preferably, the substrates are parallel or nearly parallel to each other.

The sealing material used to seal the substrates together to form the sealed module can be one or more sealing material or a sealing system that will effectively provide for an adequate seal. Preferably, the seal is airtight. By airtight we mean that the seal does not allow for the transmission of air through or around the seal. While in time it is expected that some air may diffuse or leak through the seal, the seal, when first applied, preferably should resist the penetration or air or moisture (water or water vapor) at ambient pressure, at the usual outdoor temperatures, and at the variety of weather and other ambient conditions existing throughout the world during any season.

The sealant material used to form the seal is preferably an elastomer, or other polymeric or rubbery material, either synthetic or natural. It can be a combination of materials. For example, the seal can be comprised of silicone, butyl rubber, polyisobutylene, hot melt butyl, curable polyisobutylene hot melt, polysuflide or other similar material.

Preferably, the sealant material used to form the seal in this invention is a solid or semi-solid at a temperature of above about −40° C. to about 90° C., and preferably softens at about 90° C. or above so it can be applied to the substrate in a softened form to provide for an excellent seal to the substrate surface. The seal of this invention can be a multi-component seal which comprises two or more seals. The seals in the multi-component seal can be placed next to or near each other, and each seal in the multi-component seal can be of the same or different sealant materials. Near each other means, preferably, spaced about 0.01 to about 1.0 inch from each other. For example, the seal can comprise an inner and outer seal in relation to the chamber formed by the seal and the substrate. The inner seal can comprise, for example, a polyisobutylene material, while the outer seal of the two component seal can comprise, for example, a silicone, polysulfide or hot melt butyl or curable polyisobutylene hot melt.

The seal or one or more of the seals in a multi-component seal, can contain a spacer, structural or reinforcement member such as a solid or hollow plastic, metal or hard rubber bar or tube. The bar or tube can be of any shape. Preferably, the sealant materials used in the seals of this invention are of very low electrical conductivity or, preferably, are not electrically conductive. For example, they have a dielectric constant of 2.0 or greater than 2.0. Also, to add structural strength to the sealant materials, they preferably contain one or more fillers such as glass fibers or beads, or silica or other, preferably, non-conducing filter. The amount of filler can be about 1% to about 60% by weight of the sealant material.

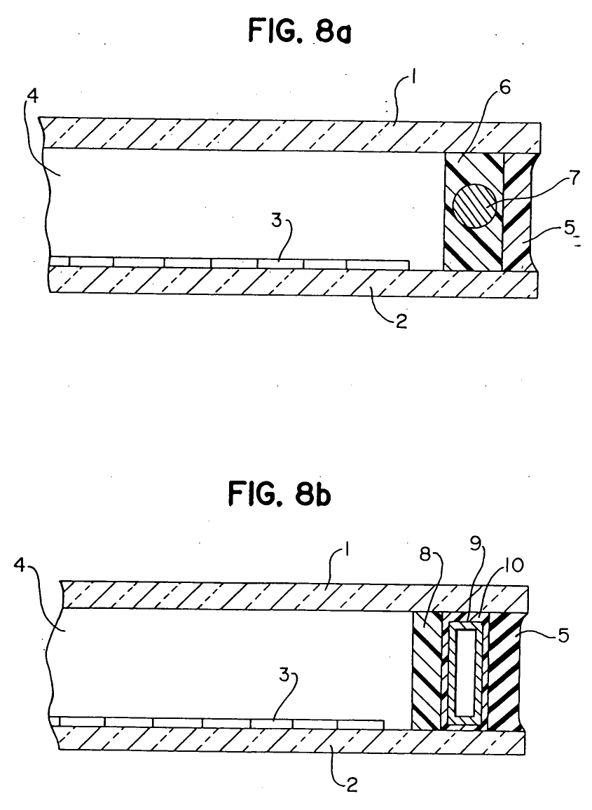

FIGS. 8(a) and 8(b) show two embodiments of the present invention. Both FIGS. 8(a) and 8(b) show the cross-section of a sealed module of this invention at one edge showing the detail of the seal. In both Figures, 1 is a first substrate and 2 is a second substrate, preferably flat glass. Thin film photovoltaic device 3 is formed on second substrate 2. The seal and substrate form chamber 4 which has the photovoltaic device 3 contained therein. In FIG. 8(a), the seal is a two component seal containing outer seal 5 comprising, for example, silicone, polyisobutylene, curable polyisobutylene hot melt, polysulfide hot melt butyl or the like. Inner seal 6 can comprise, for example, a polyisobutylene. In this embodiment, inner seal 6 also comprises an optional structural member 7 in the form of a bar with a circular cross section. Although shown as a solid bar, it can be hollow and of any cross sectional shape. It can be made of metal, such as steel or aluminum, or of a synthetic material such as plastic or hard rubber such as ethylene propylene diene monomer (EPDM) rubber, or of another suitably rigid or strong material. It can have a width (cross section) of about 0.1 to about 0.3 inch, or more. Generally, inner seal 6 is formed first and outer seal 5 is applied after substrates 1 and 2 have been jointed by seal 6. Outer seal 5 can be applied around the edge of the module to fill in the space between inner seal 6 and the outer edges of substrates 1 and 2.

In FIG. 8(b), the seal is a three component seal. Inner seal 8 can comprise a polyisobutylene, optionally containing a desiccant either within the polyisobutylene material or on the inside surface (relative to the sealed chamber) of the polyisobutylene seal, or similar material. Outer seal 5 can comprise a silicone, hot melt butyl, curable polyisobutylene hot melt, polysulfide material and the like. The inner seal in this embodiment comprises a spacer or structural element 9 coated with a sealant material such as one of the materials used for inner seal 8 and outer seal 5 mentioned above. Spacer or structural element 9 can be metal, such as aluminum or steel, or it can be a rigid polymer material such as EPDM rubber. It can be hollow or solid. Preferably, it is of rectangular or square shape. If it is constructed of a metal, the coating 10 is preferably a material that has a low or no electrical conductivity, preferably having a dielectric constant of 2.0 or greater than 2.0.

The seal, as mentioned above, preferably runs along or around the perimeter or near the perimeter of the substrates. The width of the seal will depend on the size of the substrate, the spacing of the substrates from each other and the structural requirements of the sealed module. However, in most applications the seal will be about 0.1 to about 0.75 inch in width. As used in this patent application, “near the perimeter” preferably means the outer edge of the seal is about 0.2 to about 1.0 inch, or, preferably, 0.25 to about 0.75 inch, from the edge of the substrate. As described above, it is preferable for the sealed module to be air tight or hermetically sealed to prevent atmospheric elements, particularly moisture, from entering the chamber containing the thin film photovoltaic device. However, it is to be understood that the invention is not to be so limited.

The seal that runs along the perimeter or near the perimeter of the sealed module is preferably but not necessarily of the same construction around the entire perimeter. There can be one or more types of seal present in the sealed module. Additionally, a portion of the seal can be designed to permit the passage of electrical wires or other electrical conductors through the seal. Although in one embodiment, the wires or other electrical conductors pass through the seal material as shown, for example, in FIG. 1, it is also contemplated in this invention that the wires or other electrical conduits can be part of a separate unit that is positioned in and forms part of the total seal such as a block.

In the preferred method of making the sealed photovoltaic modules of this invention, a first substrate, preferably a flat glass substrate, having a thin film photovoltaic device deposited thereon, for example, an amorphous silicon thin film or CdS/CdTe device, is sealed to a second substrate using a seal running around or along or near the edge of the substrate. In some instances, the photovoltaic device will cover the entire surface of the first substrate. In that case, it is preferable to remove the films of the thin film device in the region around the edge of the first substrate in order to provide for a clean surface for the seal material to adhere to. The thin film device can be removed by scraping, sanding or other means to mechanically remove or abrade the material from the surface of the substrate. In the preferred method of this invention, the material selected to from the seal is heated to a temperature to soften the seal material so it can form a tight, moisture resistant seal with the surface of the substrate. The softened seal material is then applied to one of the substrates on the side that will be facing the chamber. Generally, the seal material is applied to the substrate in a bead or strip, preferably having a rectangular or square cross section, and is preferably applied completely around the substrate. While the sealant material is still at a temperature that provides for a softened seal material, the first and second substrates, preferably each of the same size, are positioned next to each other so that the bead or strip of sealant material contacts the other substrate and forms the seal around the perimeter or near the perimeter of the substrates and joins the substrates together with a moisture resistant seal and forms a sealed chamber bounded by the inner surface of the seal, and the inner surfaces of the substrates. If the first seal is placed near the edge of the substrates rather than at the edge, an additional outer seal to such an inner seal can be applied by filling in the space formed by the edges of the substrates and the inner seal with, for example, a second seal material.

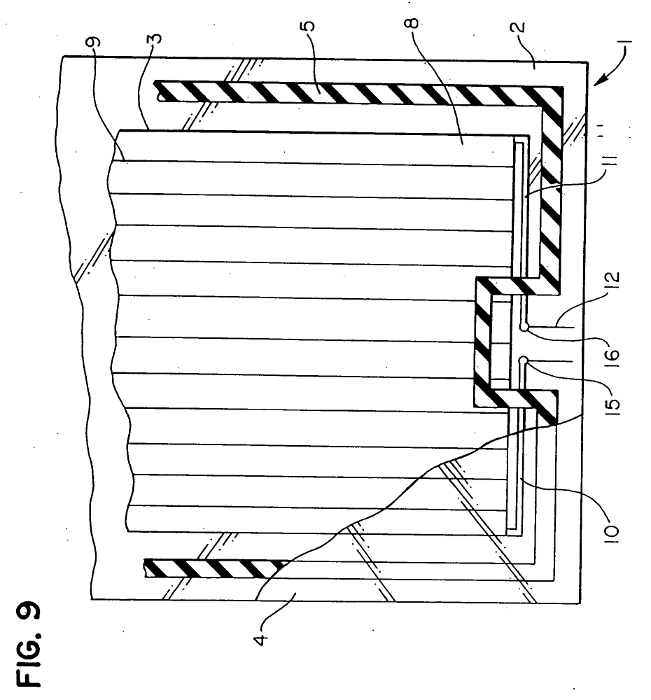

FIG. 9 shows an embodiment of the invented sealed module where the seal is directed around the area where the electrical conductors are located.

In FIG. 9, which is a view of the module from the topside, i.e., substrate 2 is below substrate 4 in this view, the elements shown are numbered according to the same elements in FIG. 1. Thus, module 1 has photovoltaic device 3 deposited on substrate 2, preferably glass, with individual photovoltaic cells 8 separated by interconnects 9. However, in the module of FIG. 9, the electrical connectors (e.g. bus bars) 10 and 11 are relatively flat or low profile strips of a cured conductive paste leading up to solder points 15 and 16, respectively, where connector 12 is soldered or otherwise connected thereto. In this embodiment, as shown, the seal 5 is directed around the region where the electrical connector 12 is connected to electrical connectors 10 and 11. In this embodiment, the flat, low profile connectors 10 and 11 pass under the seal 5. Connectors 10 and 11 can be bus bars as described hereinabove and, although not shown in FIG. 9, the bus bars can run along outside of each end of end cells in photovoltaic device 3.

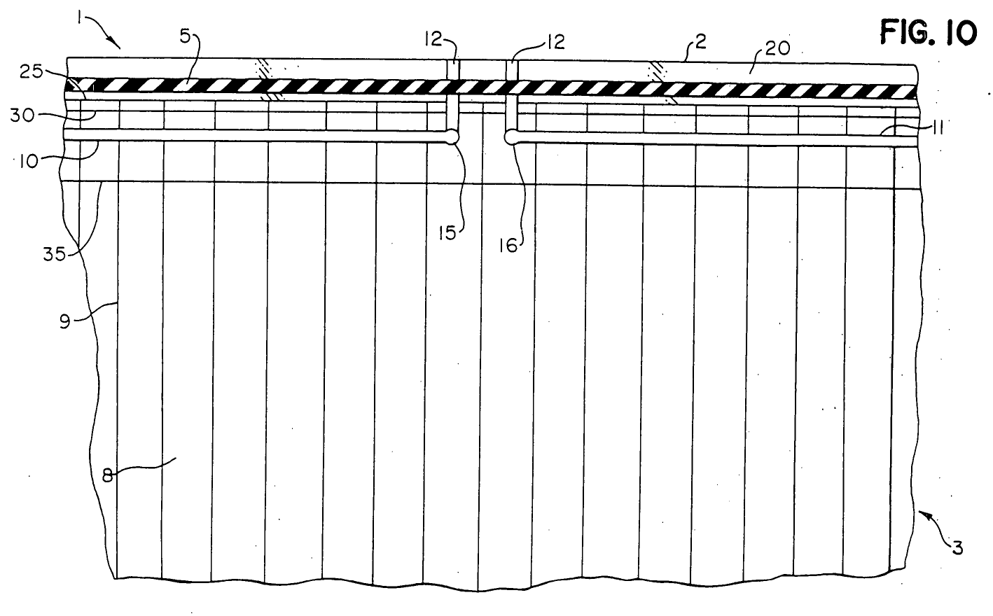

FIG. 10 shows another embodiment of the invented module. FIG. 10, like FIG. 9, is a view looking at the topside of the module and an exploded view of the region where the electrical connectors are located. However, in this embodiment, the electrical connectors (e.g. bus bars) 10 and 11 are placed on the photovoltaic element 3. All elements having the same number in FIG. 10 as FIG. 9 are the same elements. In the module of FIG. 10, a portion of the thin film photovoltaic element 3 has been removed from the substrate 2 by scraping or otherwise abrading the thin film photovoltaic device to remove a band or border of the thin film device around the perimeter of substrate 2, forming a region 20 without any photovoltaic elements deposited thereon. This cleaned area provides for a better contact for seal 5. The photovoltaic device material is removed from the edge of substrate 2 to a position shown as 25 in FIG. 10.

Laser scribe lines 30 and 35 isolate the section of photovoltaic device 3 from the area having the electrical connectors 10, 11 and 12. Scribe lines 30 and 35 are through all layers of photovoltaic device 3. In FIG. 10, electrical connectors 12 are flat strips of copper or other conductive metal foil, which have been laminated on each side with a non-conductive insulating material such as Kapton tape. Only the portion of the metal foil soldered to solder points 15 and 16 and the opposite end of the metal foil are-free of the insulating material. The coated metal foil connectors 12 are cemented to substrate 2 with a suitable adhesive. As shown in FIG. 10, the “strips” of electrical connector 12 pass under the seal material of seal 5. In FIG. 10, substrate 4 is not shown.

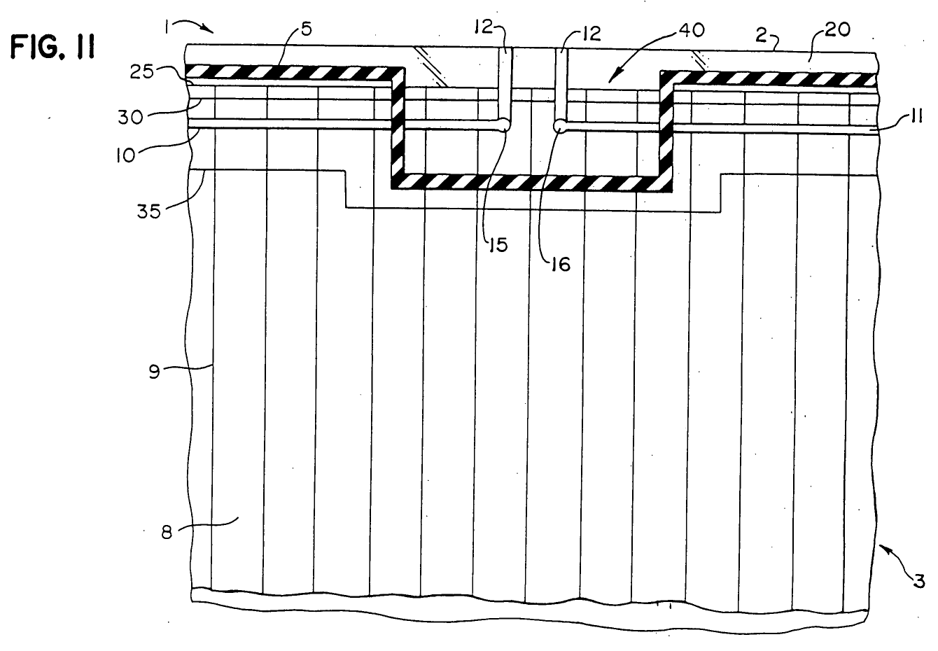

FIG. 11 is another embodiment of the instant invention. In this Figure, which is also a topside view of the module (substrate 4 is not shown) numbered elements are the same as shown in FIG. 10. In FIG. 11, the seal 5 is directed around the region of the module where the electrical connectors are located. In the module of FIG. 11, seal 5 is placed on the photovoltaic element 3 in the region around the electrical connectors. The “pocket” region 40 formed by the seal can be filled with sealant material, such as a silicone, to seal the entire pocket region. In addition, the entire region or volume outside the seal 5 to the edge of the substrate can be filled with a second sealant, such as a silicone, to provide for additional protection against the penetration of moisture, dust or other elements.

In the sealed module of this invention, a desiccant can be placed in the seal or in the chamber to absorb moisture present at the time the module is sealed and to absorb moisture that may, in time, leak in to the sealed module. Such desiccant materials include components that absorb or adsorb water molecules such as molecular sieves or zeolite materials, dehydrated clays, silicates, aluminosilicates, and the like. It can also be a material that chemically reacts with water such as inorganic or organic anhydrides, or anhydrous compounds. These chemical agents can be mixed in with the sealant material or can be grafted to the polymer chains in the sealant material. Other desiccant agents include chemical compounds such as calcium chloride or magnesium sulfate that form hydration complexes with water molecules. Any such water absorbing or adsorbing material can be used. The amount of desiccant material, if in the sealant material, will vary depending on the efficacy of the material and its effect on the physical properties of the sealant material. However, generally, the sealant material will contain about 0.1% to about 10% by weight desiccant, if a desiccant is used. The desiccant can also be placed in the spacer, if used. The desiccant can also be placed on the inside surface of the seal facing the sealed chamber.

The sealed module of this invention resists the penetration of moisture which can damage a thin film photovoltaic device and reduce its ability to generate electricity from sunlight. The modules of this invention preferably have a moisture vapor transmission rate (MVTR) of about 0 to about 0.75, preferably less than about 0.5 and most preferably less than about 0.2 g/m2/day (grams of water vapor per square meter of the surface of the module per day), the modules of this invention preferably having such MVTR when measured at 85° C. in air of about 85% relative humidity. In prior art thin film photovoltaic devices, an encapsulant such as EVA or a silicone, a polyvinylbutyl polymer or a polyurethane was used to encapsulate the entire thin film photovoltaic device to preclude or reduce degradation by, for example, moisture. However, in the sealed modules of this invention, such encapsulant covering or encapsulating the thin film photovoltaic device is not required, and it is preferable not to use such an encapsulant. Thus, in the preferred module of this invention, the thin film device deposited on one of the substrates is inside the chamber and is not covered or otherwise protected except by the sealed chamber.

The modules of this invention show highly effective resistance to the ingress or penetration of moisture to the photovoltaic elements located within the sealed module. One effective method for measuring the resistance to moisture penetration is to submit the finished module to an accelerated moisture resistance test as set forth in the International Electrical Commission (IEC) 1215 International Standard, or an equivalent test procedure. In this test procedure, the electrical characteristics of a module are first measured under standard conditions such as one (1) sun of illumination at a module temperature of about 25° C. The module is subsequently exposed to humid air at an elevated temperature for 1000 hours. The humid air has a relative humidity of about 85% and the air temperature is about 85° C. During this testing, the module, if it is susceptible to moisture penetration and the resulting degradation of module performance, will experience a decrease in electrical characteristics relative to the module before accelerated testing when measured again under standard conditions. The electrical characteristics typically measured are maximum power, short-circuit current, open-circuit voltage, efficiency and fill-factor.

When tested according to the IEC method described above or equivalent method, the modules of this invention, preferably when the thin film photovoltaic device is an amorphous silicon thin film device, exhibit a decrease in power output of no more that about 10%, preferably no more that about 5%, more preferably no more than about 1% and most preferably no more than about 0.1% Thus, the sealed modules of this invention are highly effective at resisting the ingress or penetration of moisture into the photovoltaically active elements of the photovoltaic module.

One or more of the substrates of the sealed module, particularly if the thin film device is partially transparent, and preferably if it is partially transparent by laser scribing as described above, can be coated with one or more coatings such as tin oxide, indium tin oxide or oxide-metal-oxide coatings.

In some manufacturing processes for depositing a thin film photovoltaic device on a substrate, the thin film device extends to or close to the edge of the substrate. In such cases, it is desirable to remove a sufficient portion of the photovoltaic device to provide for an area around the perimeter of the photovoltaic device. The removal can be by abrasion, scraping or other similar technique to provide for a smooth, clean surface that will durably adhere to the seal material used to seal the module.

U.S. Provisional Patent Application No. 60/337,897 filed on Nov. 5, 2001 is hereby incorporated by reference in its entirety.

### EXAMPLE

### Example 1

A partially transparent PIN thin film photovoltaic device having a transparent front contact, amorphous silicon semiconductor layers, and metallic back contact was deposited on a glass substrate using alternate deposition and laser scribing steps as described herein above. Cells in the thin film device were connected in series by interconnects as described herein. The contacts and PIN layers covered one entire side of the substrate. All of the PIN and contact layers were mechanically removed from the edge of the substrate to about 12 mm in from the edge or the substrate. A laser scribe about 0.002 inch in width was made around the entire perimeter of the thin film device and cut through all layers that were deposited. The scribe separates the photovoltaically active area from the edge of the module. The device also had deposited thereon silver-containing frit electrical connectors (bus bars), connecting the positive and negative ends of the device and ending in solder contacts positioned at the center of one edge of the device and outside the isolation scribe, but still on a portion of the photovoltaic device that was not mechanically removed. A contact consisting of 0.010 inch thick copper foil held between two layers of 0.010 inch thick Kapton tape with silicone adhesive was soldered to the positive and negative silver frit contacts. The Kapton foil served as an insulator to cross the area of the photovoltaic device remaining in that region without shorting. Bare copper foil protruding out of each end served as the means for connecting the device to the power grid or to some device using the electrical energy generated by the photovoltaic device. Ultraviolet curable acrylic was applied to the outside of the Kapton foil and then adhered to the glass perimeter of the photovoltaic module by curing with ultraviolet light through the glass. This sealed one surface of the Kapton foil to the glass substrate plate. A thermoplastic material, such as TPS available from Chemetall, which contains a desiccant, was heated to 200° F. and applied to the perimeter of the glass substrate about 6 mm in from the glass edge in a rectangular cross section from 4-6 mm wide and 10-12 mm thick. This continuous rectangular strip of thermoplastic was also applied over the Kapton covered copper foil electrical contacts to complete the perimeter and seal the electrical contact in place. A second section of uncoated glass of the same size as the substrate was pressed onto the thermoplastic while it was still warm such that both pieces of glass were adhered to each other with a space of about 10mm between them. A silicone material was then applied from the outside edge of the thermoplastic material to the edge of the glass around the entire perimeter between the two glass substrates thus forming a secondary seal around the insulated glass unit and the electrical contact. The Kapton/copper foil contact protruded beyond the secondary seal, allowing for the soldering of external wires.

### Example 2

An NIP photovoltaic thin film device was deposited and laser scribed as in Example 1. An insulated glass unit was formed as in Example 1 but using a high transmission low iron glass substrate as the second section of glass. The photovoltaic module served as the back or interior glass of the sealed module and solar radiation is let in through the front low iron glass and impinges NIP device positioned on the substrate.

### Example 3

A photovoltaic module was produced as in Example 1. The laser scribe around the perimeter of the photovoltaic module, which separates the photovoltaically active area from the edge of the module, was indented at the solder points for the wires. The indentation was rectangular and about 0.625″ into the active area and about 2″ long. This isolation scribe formed a pocket around the frit contacts. A standard 18 gauge insulated wire was soldered to each contact point. The thermoplastic material with desiccant was applied as in Example 1 but followed the isolation scribe line around the wire contact points. When the second section of glass was pressed onto the thermoplastic, a three-dimensional pocket containing the wires was formed, outside of the dry air space. This eliminated the need for penetrating the dry air seal with the external wires. The perimeter of the module formed was filled with silicone sealant as in Example 1. The indented pocket was filled with the silicone surrounding the wires.

What is claimed is:

1. A sealed photovoltaic module comprising:
a first substrate,
a second substrate,
a seal between the first and second substrates positioned at or near the edges of the substrates and forming a sealed chamber defined by the first and second substrates and the seal, and
at least one thin film photovoltaic element positioned between the first and second substrate and at least partly within the chamber.

2. The sealed module of claim 1 wherein the photovoltaic element comprises amorphous silicon.

3. The sealed module of claim 1 wherein at least one of the substrates is flat glass.

4. The sealed module of claim 2 wherein the photovoltaic element is deposited on one of the substrates and is completely within the chamber.

5. The sealed module of claim 1 wherein the photovoltaic element is deposited on one of the substrates and is not encapsulated with an encapsulating material.

6. The sealed module of claim 1 wherein the first and second substrates are spaced by about 0.1 to about 2.0 inches apart.

7. The sealed module of claim 1 further comprising a spacer positioned between the first and second substrates next to or near the seal.

8. The sealed module of claim 1 wherein the seal comprises one or more of silicone, butyl rubber, polyisobutylene, hot melt butyl, curable polyisobutylene, or polysulfide.

9. The sealed module of claim 1 wherein the photovoltaic device is a cadmium sulfide/cadmium telluride device.

10. The sealed module of claim 1 further comprising a desiccant.

11. The sealed module of claim 1 wherein the photovoltaic device is semitransparent.

12. The sealed module of claim 1 further comprising flat electrical connectors for connecting the photovoltaic module to the power grid or to some device using the electrical energy generated by the photovoltaic module.

13. The sealed module of claim 12 wherein the electrical connectors are positioned between one of the substrates and the seal.

14. The sealed module of claim 12 wherein the electrical connectors are outside of the sealed chamber.

15. The sealed module of claim 12 wherein the electrical connectors comprise metal foil.

16. The sealed module of claim 1 wherein the seal is at least a two component seal having at least an outer and an inner component.

17. The sealed module of claim 16 wherein the seal comprises at least two different seal materials.

18. A sealed photovoltaic module comprising:
a first substrate,
a second substrate,
a means for sealing the first and second substrates positioned at or near the edges of the substrates thereby forming a sealed chamber defined by the first and second substrates and the means for sealing the substrate, and
at least one thin film photovoltaic element positioned between the first and second substrate and at least party within the chamber.

19. A method for making a photovoltaic module comprising:
forming a thin film photovoltaic device on a first substrate, and
sealing the first substrate to a second substrate at or near the edges of the substrates thereby forming a sealed chamber defined by the substrates and the seal wherein the photovoltaic element is at least partially within the chamber.

20. A building facade comprising the module of claim 1.

21. The sealed module of claim 1 wherein the substrates are parallel to each other and spaced about 0.1 to about 1.0 inch apart.

22. The sealed module of claim 1 wherein the seal has a width of about 0.1 to about 2.0 inches.

23. The sealed module of claim 16 where each seal in the at least two component seal has a width of about 0.1 to about 2.0 inches.
